(19) United States
(12) Patent Application Publication
(10) Pub. No.: US 2011/0100452 A1
(43) Pub. Date: May 5, 2011

(54) SOLAR ENERGY COLLECTOR AND METHOD OF MANUFACTURING THE SAME

(75) Inventors: Jia-Yush Yen, Taipei (TW); Chuin-Shan Chen, Taipei (TW); Tzong-Lin Jay Shieh, Taipei (TW); Chia-Ling Wu, Taipei (TW); Hui-Ping Chen, Taipei (TW); Chen Jen Wel, Taipei (TW); Nien-Chen Lin, Taipei (TW); Yung-Bin Lin, Taipei (TW)

(73) Assignee: NATIONAL TAIWAN UNIVERSITY, Taipei (TW)

(21) Appl. No.: 12/887,177

(22) Filed: Sep. 21, 2010

(30) Foreign Application Priority Data
Nov. 5, 2009 (TW) 98137537

(51) Int. Cl. H01L 31/042; H01M 10/04

(52) U.S. Cl. 136/256; 29/623.1

(57) ABSTRACT

A solar energy collector and a method for manufacturing the same. The solar energy collector has a solar chip, conductive wires connected to the solar chip, and a securing line that secures the solar chip and the conductive wires. The solar energy collector is rollable, foldable and expandable.

### BACKGROUND OF THE INVENTION

1. Field of the Invention

This invention relates to a solar energy collector and a method of manufacturing the same, and particularly, to a rollable, foldable, expandable and flexible web-shaped solar energy collector and a method of manufacturing the same, the solar energy collector having a solar chip, conductive wires connected to the solar chip, and a securing line that secures the solar chip and the conductive wires.

2. Description of Related Art

With the rapid development of technology and the increasing demand for energy, a variety of energy generating methods have been provided, in addition to traditional energy generating methods.

Some of the methods use natural sources, such as heat, water or wind, to generate energy. However, these methods are restricted to be performed at certain places, and ordinary people cannot use or own them. In contrast, solar energy generating equipment is convenient and simple, and can be installed on the roof of a building. The solar panel collects sunlight and transforms it into electric energy with a solar chip thereof, so as to generate energy. In addition, some devices such as a solar energy hot water heater may transform light energy to electric energy.

Since the solar energy generating equipment is a very common technology, in order not to generate too less the energy, a great number of solar chips are arranged in an array and installed on a case-shaped board that has a large area, so as to collect the sunlight with the large enough board and generate abundant electric energy. However, such the traditional design increases the area and capacity of the solar panel, making the solar panel be installed on limited places such as a platform, and unable to be placed at anyplace at the user's will. Moreover, the solar panel is bulky, and is not easily to be installed, detached or removed, thereby having a limited number of applications.

Therefore, how to design solar energy generating equipment that is easily and flexibly installed and used has becoming one of the urgent issues in the art.

### SUMMARY OF THE INVENTION

In view of the above-mentioned problems of the prior art, a solar energy collector is provided, thereby facilitating convenient and flexible installation and use of solar energy equipment.

A solar energy collector and a method of manufacturing the same are provided. The solar energy collector includes: an energy generating unit having at least one solar chip that has two contact terminals independently connected to each of conductive wires, wherein the at least one solar chip and the conductive wires are secured with a securing line; the conductive wires and the securing line further constitutes a web structure.

In another aspect, the energy generating unit is formed by a plurality of solar chips that are connected in series via the conductive wires. Further, a plurality of energy generating units is contained in the solar energy collector, and are connected in parallel via the assembly wire, so as to form the web structure.

Another embodiment of a solar energy collector of the present invention includes: a web member; and a solar chip that has two contact terminals independently connected to each of conductive wires, the solar chip and/or the conductive wires being secured to the web member. A connection portion where the conductive wires are independently connected to the two contact terminals is encompassed with a protection member.

In another aspect, the web member is composed of a plurality of securing lines, wherein the securing lines encompass the conductive wires, and the contact terminals of the solar chip are respectively connected to the conductive wires in the securing lines.

The solar energy collector further includes an assembly wire for connecting with the conductive wires, to store energy transformed by the solar chip into an energy storage equipment.

The method of manufacturing a solar energy collector includes the following steps of: (1) connecting two contact terminals of at least one solar chip to conductive wires, respectively, to form an energy generating unit; (2) connecting a plurality of the energy generating units via an assembly wire; and (3) providing a securing line to secure the plurality of energy generating units, such that each solar chip is installed toward the same direction.

The above step (3) is formed by any one of the following aspects: entangling and securing the solar chip with the securing line; adhering the solar chip to the securing line with adhesive; inlaying and securing the conductive wires or the securing line into a groove provided on a back side of the solar chip; or penetrating the securing line with an acicular protrusion provided on a back side of the solar chip, so as to secure the solar chip to the securing line.

Another embodiment of a method of manufacturing a solar energy collector of the present invention includes the following steps of: (1) providing a web member; (2) securing at least one solar chip to the web member; and (3) connecting two contact terminals of the solar chip to conductive wires, respectively, and securing the conductive wires to the web member.

The above step (3) is formed by any one of the following aspects: securing the solar chip to the web member by a binding method; adhering the solar chip to the web member with adhesive; inlaying and securing the securing line into a groove provided on a back side of the solar chip; or penetrating the web member with an acicular protrusion provided on a back side of the solar chip, so as to secure the solar chip to the web member.

In another aspect, the web member is composed of securing lines, and the conductive wires are installed within the securing lines, such that the contact terminals of the solar chip are connected to the conductive wires, so as to secure the solar chip to the web member.

Compared with the prior art, a solar energy collector and a method of manufacturing the same of the present invention form an energy collecting device having a web structure through the combination a solar chip and conductive wires with a securing line. Since constituted by the conductive wires and the securing line, the web structure is elastic and flexible, and has more advantages, as compared with a traditional solar panel. The solar energy collector of the present invention can be installed according to environment needs, and is easily to be detached or removed.

### BRIEF DESCRIPTION OF DRAWINGS

The invention can be more fully understood by reading the following detailed description of the preferred embodiments, with reference made to the accompanying drawings, wherein:

FIG. 1A is a schematic diagram of a solar energy collector of an embodiment according to the present invention;

FIG. 1B is a schematic diagram of a solar energy collector of another embodiment according to the present invention;

FIG. 2 is a schematic diagram of an energy generating unit of a solar energy collector of an embodiment according to the present invention;

FIG. 3A is a schematic diagram of an energy generating unit of a solar energy collector of another embodiment according to the present invention;

FIG. 3B is a schematic diagram illustrating securing an energy generating unit with a securing line of another embodiment according to the present invention;

FIG. 4A shows an solar energy collector having a web member of an embodiment according to the present invention;

FIG. 4B shows an solar energy collector having a web member of another embodiment according to the present invention;

FIG. 5 is a partial schematic diagram of an solar energy collector having a web member of yet another embodiment according to the present invention; and

FIGS. 6-9 are schematic diagrams illustrating securing ways to secure a solar chip of a solar energy collector according to the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without detaching from the spirit of the present invention.

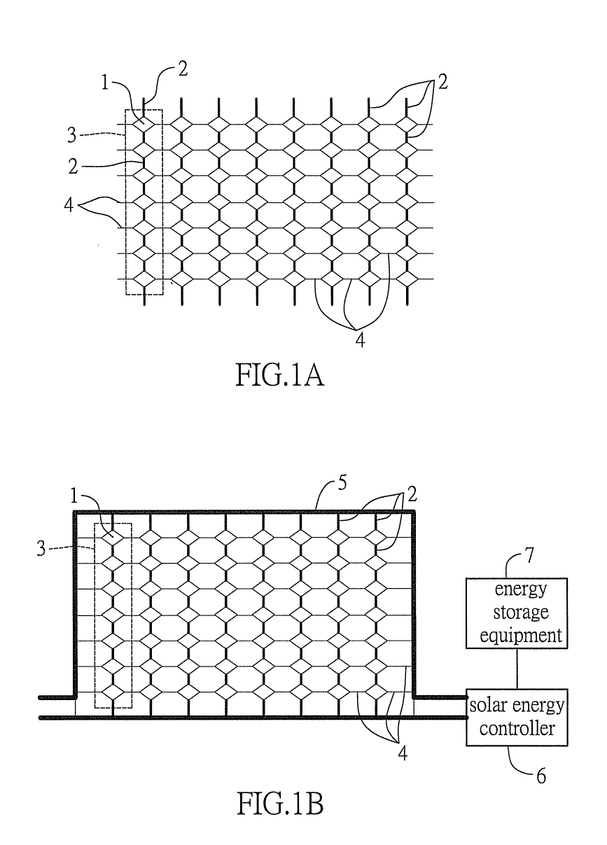

FIG. 1A is a schematic diagram of a solar energy collector of an embodiment according to the present invention. The solar energy collector comprises an energy generating unit 3 and a securing line 4. The energy generating unit 3 has a plurality of solar chips 1, each of which has two contact terminals connected to respective conductive wires 2 for transmitting energy. Connecting a plurality of solar chips in series with the conductive wires 2 may form the energy generating unit 3 that comprises a plurality of solar chips 1 and provides more energy, as compared to another energy generating unit having only one solar chip. A securing line 4 secures the energy generating unit 3. The securing line 4 and the conductive wires 2 of the energy generating unit 3 are combined to form a web structure.

FIG. 1B is a schematic diagram of a solar energy collector of another embodiment according to the present invention. The solar energy collector comprises an assembly wire 5. The assembly wire 5 is connected to each of the energy generating units 3 that are connected in the shape of a web. The assembly wire 5 is further electrically connected to a solar energy controller 6, and stores energy transformed by the solar chips 1 via the solar energy controller 6 to energy storage equipment 7. The assembly wire 5 is connected to the head and tail end conductive wires 2 that are located at the outermost of the energy generating unit 3 (i.e. the conductive wires that extend to the end and are not connected to a solar chip) to form a parallelly connected energy collecting loop. The energy collecting loop transmits the energy generated by the whole solar chips 1 to the solar energy controller 6. The securing line 4 that is connected to the transversely outermost energy generating unit 3 is also connected to the assembly wire 5, allowing the whole energy generating units 3, the securing lines 4 and the assembly wires 5 to form a flexible web structure. The solar energy controller 6 controls the storage of energy or the transformation of the stored energy. In other words, the solar energy controller 6 controls the access of all energy. The energy storage equipment 7 stores energy. In an embodiment, the energy storage equipment 7 is a secondary battery or equipment for storing energy.

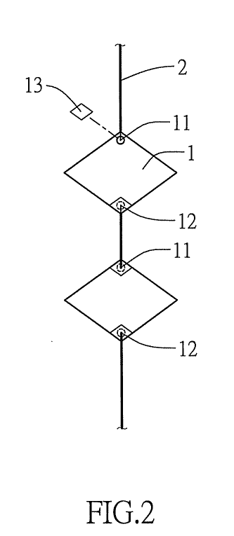

FIG. 2 is a structural schematic diagram of an energy generating unit of a solar energy collector according to the present invention. Contact terminals of the conductive wire 2 and the solar chip 1 are encompassed with a protection member 13, for protecting the connection portion between the conductive wire 2 and the contact terminals. The protection member 13 prevents rain or external objects from contacting or pulling the connection portion, and protects the connection portion from poor connection or being broken. As described previously, the solar chip 1 has two contact terminals, one of which is a positive electrode and the other of which is a negative electrode. As illustrated in the embodiment shown in FIG. 2, the solar chip 1 comprises a positive electrode 11 and a negative electrode 12. All of the solar chips 1 in each of the energy generating units are connected in series. Except one end of the solar chip that is located at front and rear outer sides of the energy generating unit 3, which is connected to the assembly wire 5, the positive electrode 11 of the remaining solar chips are connected to the negative electrodes 12 of the solar chips that are connected to the solar chip in series. Besides, the negative electrode 12 of each of the solar chips is connected to the positive electrode 11 of a solar chip connected to the solar chip in series. Accordingly, the currents generated by the solar chips 1 connected in series flow toward the same direction, so as to achieve energy collecting effect.

In addition to using the protection member 13, as shown in FIG. 2, as a protection connection way of the conductive wire 2 and the solar chip 1, other connection ways are used for connecting the solar chip and the conductive wire or the securing line of the energy generating unit of the solar energy collector of the present invention. For instance, a groove is formed on the back side of the solar chip 1, for fastening with the conductive wire 2 and the securing line 4. Therefore, the solar chip 1 is steadily fastened to the conductive wire 2 or the securing line 4. In another embodiment, an acicular protrusion is further provided on the back side of the solar chip 1, for penetrating and fastening to the securing line 4. Therefore, the solar chip 1 is steadily fastened to the securing line 4. The above fastening ways will be described in the following method of manufacturing a solar energy collector.

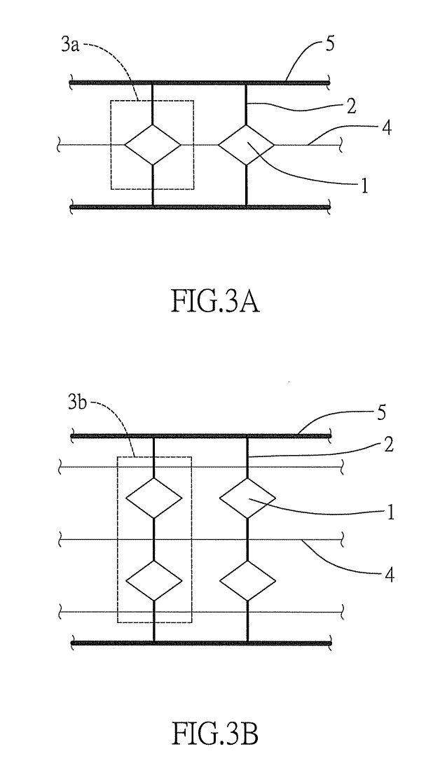

The energy generating unit 3 is not limited to comprise the number of solar chip 1 shown in FIG. 1B. FIG. 3A shows an energy generating unit of a solar energy collector of another embodiment according to the present invention. In the another embodiment, a plurality of energy generating units 3a are composed of a single solar chip 1. The securing lines 4 and the energy generating units 3a intersect at the solar chip 1, so as to achieve fastening effect. The conductive wires at two ends of the solar chip 1 are connected to the assembly wire 5.

The energy generating unit, which is fastened by the securing line, is not limited to be fastened by the above method. FIG. 3B shows another embodiment illustrating fastening an energy generating unit 3b with a securing line. The energy generating unit 3b in the another embodiment is composed of two solar chips 1, and is connected in parallel through the assembly wire 5. The securing line 4 intersects the conductive wire 2 between the two solar chips, such that the energy generating unit 3b unlikely shakes. In the another embodiment, the energy generating unit 3b is composed of two solar chips 1, and a plurality of energy generating units 3b that are connected in parallel and the securing line 4 form a web structure. It is noteworthy that the above number can be adjusted according to practical needs, and the figure is for illustration and is not intended to limit the number.

There is another embodiment for the solar energy collector of the present invention. The solar energy collector of the another embodiment comprises a web member and at least one solar chip having two contact terminals connected to conductive wires, respectively, wherein the solar chip and/or the conductive wires are fastened to the web member. The web member is composed of a plurality of securing lines and has a rollable, foldable and flexible weaved or un-weaved structure that is in the shape of a bar, strip or slice. The connection portion of the conductive wire and the contact terminals of the solar chip is encompassed with a protection member. The protection member prevents rain and external members from contacting or pulling the connection portion, and protects the connection portion from poor connection or being broken.

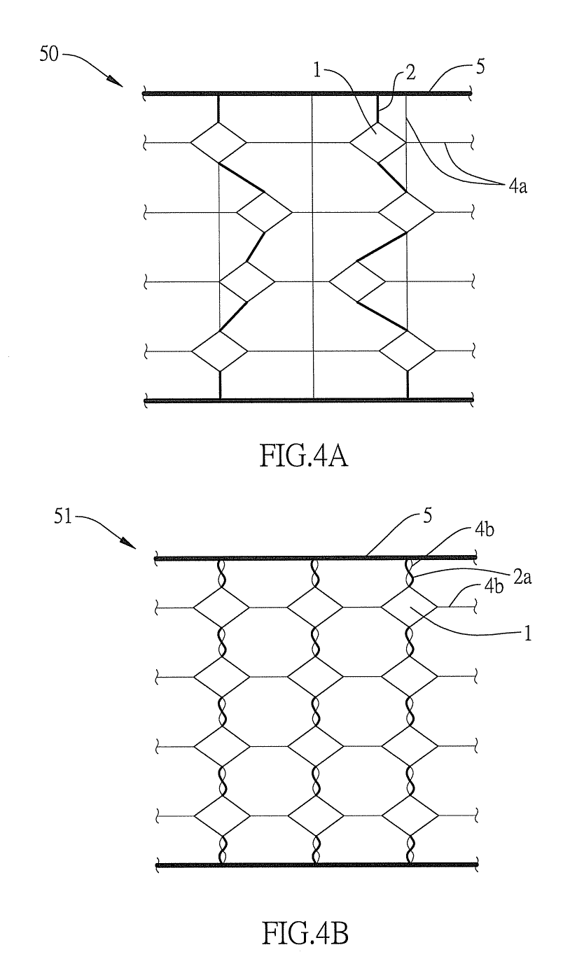

FIG. 4A is a schematic diagram of an embodiment for illustrating the above solar energy collector of the present invention that comprises the web member. The solar chips 1 are arranged in series through the conductive wire 2. Each of the solar chips 1 is secured to a web member 50 that is composed of a securing line 4a. There is no limitation to the position where the solar chip 1 is located on the web member 50. The solar chip 1 may be located at an intersect of the web member or on the securing line 4a. After the solar chips 1 are connected in series via the conductive wire 2, the conductive wires of the solar chips 1 at ends of the outer sides are connected to the assembly wires 5, respectively. The assembly wires 5 are electrically connected to the solar energy controller 6 (referring to FIG. 1B), to store the energy transformed by the solar chip via the solar energy controller 6 to the energy storage equipment 7 (referring to FIG. 1B).

FIG. 4B is a schematic diagram of another embodiment for illustrating the above solar energy collector of the present invention that comprises the web member. The web member 51 is composed of a securing line 4b. the solar chip 1 is disposed on the web member 51. Each of the conductive wires 2a is entangled with the securing line 4b, so as to achieve fastening effect. It is noteworthy that the conductive wire 2a is not limited to the above way of fastening the securing line 4b by entanglement. Any alternative ways could be used in the present invention, as long as the conductive wire 2a is cable of being installed along the securing line 4b and results in no shaking or detachment of the solar chip 1.

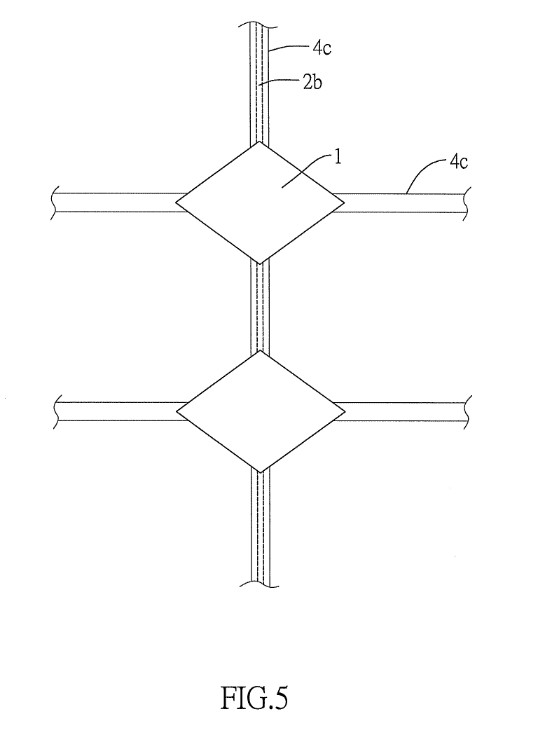

FIG. 5 is a partial schematic diagram of a solar energy collector having a web member of yet another embodiment according to the present invention. A part of the securing line 4c that constitutes the web member encompasses the conductive wire 2b. The contact terminals of the solar chip 1 are connected to the connective wire 2b in the securing line 4c only. Only two ends (not shown) of the conductive wire 2b are exposed and are connected to the contact terminals on the solar chip 1. The yet another embodiment only needs to secure the solar chip 1 to the web member, and connect the contact terminals of the solar chip 1 to the conductive wire 2b, so as to achieve an effect of securing the solar chip.

In a solar energy collector of still another embodiment that has a web member according to the present invention, a groove is formed on the back side of the solar chip, allowing the conductive wire or the securing line to be secured thereto. Accordingly, the solar chip can be steadily fastened to the web member. An acicular protrusion may be further provided on the back side of the solar chip, for penetrating and fastening to the securing line, so as to steadily fasten the solar chip to the web member.

Note that the solar energy collector is different from a traditional solar panel. The traditional solar panel packages a plurality of solar chips arranged in an array, to form a solar panel of a large area, while the solar chip of the solar energy collector of the present invention is formed as a chip of tiny capacity by a single packaging method. In addition to being in a single-chip package, the solar chip can also be packaged with the conductive wire. In other words, the solar energy collector of the present invention is mainly composed of a solar chip, conductive wire and securing line, and is manufactured by many ways, such as combining the conductive wire with the solar chip to form the energy generating unit and fastening them with the securing line, or constituting a web member with the securing line and installing the solar chip thereon and fastening the solar chip thereto. Any aspect can be applied to the present invention, as long as it can fasten the solar chip to the web structure, for providing a soft solar energy generating means. In the following paragraphs, a method of manufacturing a solar energy collector, in which the solar chip is easily to be fastened to the web structure, will be described.

The present invention provides a method of manufacturing a solar energy collector, comprising the following steps of: (1) connecting two contact terminals of at least one solar chip with conductive wires, respectively, to form an energy generating unit; (2) connecting a plurality of the energy generating units via an assembly wire; and (3) providing a securing line to secure the plurality of energy generating units, such that each of the solar chip is toward the same direction. The energy generating unit connects the solar chip with the conductive wire in series and performs a single packaging process. A plurality of sets of energy generating units are connected in parallel via the assembly wire, to form a web structure. Moreover, the connection portion where the two contact terminals of the solar chip are connected to the conductive wire is encompassed with a protection member. The securing line can be made of any suitable material such as nylon.

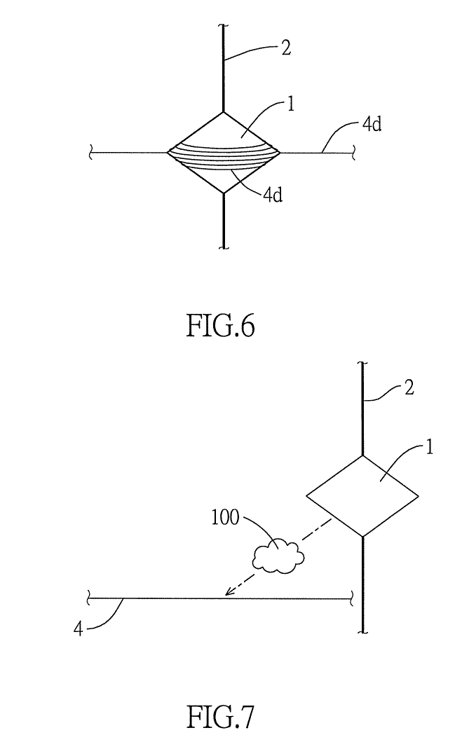

FIGS. 6-9 show securing ways to secure a solar chip in a method of manufacturing a solar energy collector according to the present invention.

As shown in FIG. 6, a securing way to secure the solar chip 1 uses a securing line 4d to entangle the solar chip 1, so as to secure the solar chip 1 to a member in web structure. It is noteworthy that the entangling method is not limited in direction and number, and even the conductive wire 2 can perform securing function under proper entanglement that the conductive wire 2 is not damaged accordingly.

As shown in FIG. 7, the solar chip 1 is secured to the securing line 4 by adhesive 100. The adhesive 100 is not limited by a certain type, as long as it does not damage the securing line 4 and the conductive wire 2.

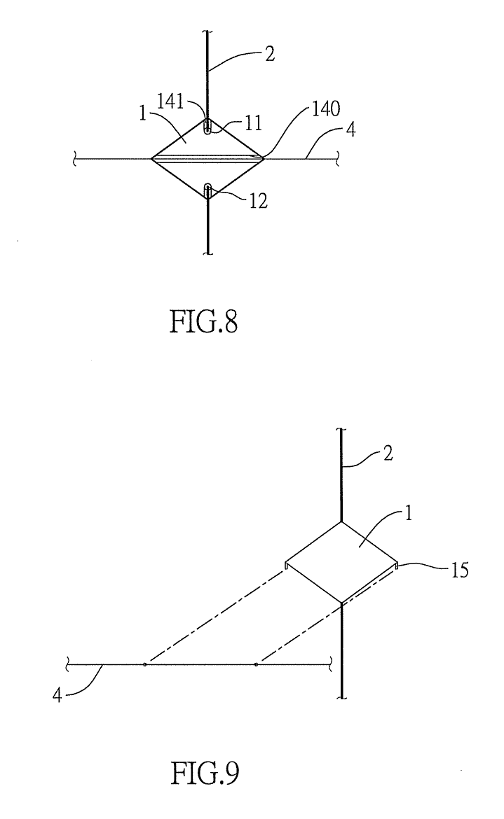

Shown in FIG. 8 is an illustration diagram of a back side (a side that does not receive light) of the solar chip 1. The embodiment is used to illustrate that the solar chip 1 is secured to the securing line of the web structure by an inlaying method. In a manufacturing process of the solar chip 1, at least a groove 140 is provided on the back side of the solar chip, such that the securing line 4 can be inlaid into the groove 140. The position where the groove 140 is disposed and the size and depth of the groove 140 can be adjusted according to practical needs during the manufacturing process. As shown in FIG. 8, an upper end and lower end of the conductive wire 2 are connected to the positive electrode 11 and the negative electrode 12, respectively. The solar chip 1 comprises a lengthwise groove 141 for insertion of the conductive wire 2.

FIG. 9 shows that the solar chip 1 is secured to the securing line 4 by an engaging method. During the manufacturing process of the solar chip 1, an acicular protrusion 15 is provided at an edge of the solar chip 1 that is approximately perpendicular to the conductive wire 2. The acicular protrusion 15 is used to be inserted into the securing line 4, to secure the solar chip 1 to the web structure tightly. As shown in FIG. 9, the acicular protrusions 15 are provided on both the left and the right ends of the solar chip 1, for being inserted into and secured to the securing line 4.

A method of manufacturing a solar energy collector of another embodiment according to the present invention comprises the following steps: (1) providing a web member that is composed of a securing line and is secured with a conductive wire; (2) securing at least one solar chip to the web member; and (3) connecting two contact terminals of the solar chip with the conductive wires, respectively. The solar chip is in a single-chip package. In other words, the solar chip is packaged directly as being manufactured, and then connected to the conductive wire when placed on the web structure. The connection portion where the two contact terminals of the solar chip are connected to the conductive wires is encompassed with a protection member. The web member is composed of a securing line. The securing line is made of any suitable material such as nylon.

The above manufacturing methods can be secured by a variety of types of securing methods, which will be illustrated with FIG. 4B together with FIGS. 7-9.

As shown in FIG. 4B, the solar chip 1 is secured to a web member 51 that is composed of the securing line 4B by entangling and securing the conductive wire 2a along the securing line 4b. Note that the securing method is not limited to a certain direction and number. The conductive wire 2a can also entangle or bind with the web member 51 to achieve securing effect, as long as the conductive wire 2a is not damaged.

As shown in FIG. 7, the solar chip 1 is secured in a manner of adhesion. The adhesive 100 adheres the solar chip 1 to the web member 51. The adhesive 100 is not limited in species, as long as it does not damage the web member 51 or the conductive wire 2.

Alternatively, as shown in FIG. 8 the solar chip 1 is inlaid and secured to the web member. During the manufacturing process of the solar chip 1, at least one groove 140 is provided on the back side of the solar chip, such that the securing line 4 of the web member can be inlaid in the groove 140. The position where the groove 140 is disposed, and the size and depth of the groove 140 can be adjusted according to practical needs during the manufacturing process. As shown in FIG. 8, an upper end and a lower end of the conductive wire 2 are connected to the positive electrode 11 and the negative electrode 12, respectively. The solar chip 1 comprises a lengthwise groove 141 for insertion of the conductive wire 2.

As shown in FIG. 9, the solar chip 1 is engaged with and secured to the web member 51. During the manufacturing process of the solar chip 1, an acicular protrusion 15 is provided at an edge of the solar chip 1 that is approximately perpendicular to the conductive wire 2. The acicular protrusion 15 is for being inserted into the securing line 4 of the web member, such that the solar chip 1 can be tightly secured to the web member. As shown in FIG. 9, acicular protrusions 15 are provided on both left and right ends of the solar chip 1, for being inserted into and secured to the securing line 4.

In another embodiment, as shown in FIG. 5, in the above web member that is composed of the securing line 4 the conductive wire is contained in the securing line 4, and has its ends exposed for connection with the conductive wire 2. In the another embodiment, the solar chip 1 can be secured to the web member by surface mount technology (SMT). Since the conductive wire 2 is placed in the securing line 4 and only the two ends of the conductive wire 2 are exposed for connection with the solar chip 1, the solar chip 1 is connected to the conductive wire 2 in the securing line 4 and the solar chip 1 can be secured to the web member by SMT technology.

In addition to providing solar energy generating effect, the solar energy collector of the present invention can also have a variety of applications because it has the web structure. For instance, the present invention may be applied to agricultural art, to replace a traditional gauze that is used for protecting crops. The traditional gauze is mainly used to protect crops from insects, rain and sunshine, and keep good ventilation. In contrast, the solar energy collector of the present invention has a web structure that is formed with a securing line or is formed by combining conductive wires and a securing line. The web structure may have any size, depending on practical needs. In addition to owning the basic functions of the traditional gauze, the solar chip can also transform solar energy to electric energy, and store the electric energy or use the electric energy as the basic electricity for agricultural peripherals. For example, the electric energy can be transformed for night lighting or a water pumping motor. Through an appropriate weave to generate gauze effect, the web structure is composed of a securing line made of a variety of materials such as nylon, and thus has elasticity and flexibility. The elasticity protects the web structure from being pulled externally and damaged. The flexibility means that the web structure does not belong to a traditional rigid board structure, and can have different applications based on practical needs. Therefore, the problem of the prior art is solved that the traditional rigid solar panel is hard to be installed and inconvenient to use. Since the solar energy collective is flexible, it can be installed at an uneven place and is easily to be detached or removed, depending on practical needs.

In sum, the present invention provides a solar energy collector and a method of manufacturing the same. An energy collecting device having a web structure is constituted by a tiny solar chip, conductive wires and a securing line. In addition to a solar energy generating effect, the web structure has elasticity and flexibility, since the web structure is formed by the conductive wires and the securing line. Accordingly, the solar energy collector of the present invention can replace a traditional solar panel and be placed in any corner of a building or at any uneven place, and is easily to be detached and removed. Moreover, the present invention constitutes the energy collecting device having the web structure with the conductive wires, solar chip and securing line, so the size of the web structure and the number of the solar chips can be adjusted according to practical needs. In comparison with the traditional solar panel that has a constant size, the solar energy collector of the present invention is more efficient and has more versatile applications.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A solar energy collector, comprising:
an energy generating unit having at least one solar chip that has two contact terminals independently connected to each of conductive wires, wherein the at least one solar chip and the conductive wires are secured with securing lines.

2. The solar energy collector of claim 1, wherein the conductive wires and the securing lines constitute a web structure.

3. The solar energy collector of claim 2, further comprising an assembly wire for connecting with the conductive wires that extend from an end portion of the energy generating unit, thereby storing energy transformed by the at least one solar chip into an energy storage equipment.

4. The solar energy collector of claim 2, wherein the solar energy collector has a plurality of the energy generating units connected in parallel via the assembly wire.

5. The solar energy collector of claim 1, wherein a connection portion where each of the conductive wires are independently connected to the two contact terminals is encompassed with a protection member.

6. The solar energy collector of claim 1, wherein the energy generating unit is formed by a plurality of the solar chips connected in series via the conductive wires.

7. The solar energy collector of claim 1, wherein a groove is provided on a back side of the at least one solar chip for insertion and securing of the conductive wires or the securing lines.

8. The solar energy collector of claim 1, wherein an acicular protrusion is provided on a back side of the at least one solar chip for penetrating and being secured to the securing lines.

9. A solar energy collector, comprising:
a web member; and
a solar chip comprising two contact terminals independently connected to each of conductive wires, the solar chip and/or the conductive wires being secured to the web member.

10. The solar energy collector of claim 9, wherein a connection portion where each of the conductive wires are independently connected to the two contact terminals is encompassed with a protection member.

11. The solar energy collector of claim 9, wherein the solar chip is connected in series.

12. The solar energy collector of claim 9, further comprising an assembly wire for connecting with the conductive wires, thereby storing energy transformed by the solar chip into an energy storage equipment.

13. The solar energy collector of claim 9, wherein the web member is composed of a plurality of securing lines.

14. The solar energy collector of claim 13, wherein the securing lines encompass the conductive wires, and the contact terminals of the solar chip are connected to the conductive wires in the securing lines.

15. The solar energy collector of claim 13, wherein a groove is provided on a back side of the solar chip for insertion and securing of the conductive wires or the securing lines.

16. The solar energy collector of claim 13, wherein an acicular protrusion is provided on a back side of the solar chip for penetrating and being secured to one of the securing lines.

17. A method of manufacturing a solar energy collector, comprising the steps of:
(1) connecting two contact terminals of at least one solar chip with each of conductive wires, respectively, to form an energy generating unit;
(2) connecting a plurality of the energy generating units via an assembly wire; and
(3) providing securing lines to secure the plurality of energy generating units, such that each of the solar chips is installed toward the same direction.

18. The method of claim 17, wherein the energy generating unit is in a single-chip package.

19. The method of claim 17, wherein a connection portion where the contact terminals are connected to the conductive wires is encompassed with a protection member.

20. The method of claim 17, wherein in step (3) the solar chip is secured with the securing line in a manner of entanglement.

21. The method of claim 17, wherein in step (3) the solar chip is adhered to the securing line with an adhesive.

22. The method of claim 17, wherein step (3) inlays the conductive wires or the securing line into a groove provided on a back side of the solar chip.

23. The method of claim 17, wherein step (3) penetrates the securing line with an acicular protrusion provided on a back side of the solar chip, to secure the solar chip to the securing line.
